(19) United States
(12) Patent Application Publication
(10) Pub. No.: US 2019/0364630 A1
(43) Pub. Date: Nov. 28, 2019

(54) ELECTRICAL CIRCUIT AND METHOD OF OPERATING AN ELECTRICAL CIRCUIT

(71) Applicant: OSRAM Opto Semiconductors GmbH, Regensburg (DE)

(72) Inventors: Andreas WOJCIK, Regensburg (DE); Hubert HALBRITTER, Dietfurt-Toeging (DE); Josip MARIC, Sinzing (DE); Martin HAUSHALTER, Regensburg (DE)

(21) Appl. No.: 16/477,983

(22) PCT Filed: Jan. 16, 2018
(86) PCT No.: PCT/EP2018/050945

§ 371 Date: Jul. 15, 2019

(30) Foreign Application Priority Data
Jan. 18, 2017 (DE) 10 2017 100 879.9

(51) Int. Cl. H05B 33/08; H02M 3/158; H01S 5/042

(52) U.S. Cl. CPC H05B 33/0818; H01S 5/0428; H05B 33/0827; H02M 3/158

(57) ABSTRACT

An electrical circuit that drives a light-emitting component including a parallel circuit including a capacitor; and a switching element, wherein a first terminal for a voltage supply connects to a first contact of the capacitor and a second terminal for a voltage supply connects to a second contact of the capacitor, the switching element includes a first electrical switch including a first input for a first switching signal, a second electrical switch including a second input for a second switching signal, and third and fourth terminals, the third terminal and the fourth terminal form a component terminal for the light-emitting component, a first current path may be switched to be conducting by the first switch, the first current path includes the component terminal, a second current path may be switched to be conducting by the second switch, and the second current path is in parallel with the component terminal.

### TECHNICAL FIELD

This disclosure relates to an electrical circuit and a method of operating an electrical circuit.

### BACKGROUND

To drive light-emitting components, in particular light-emitting diodes and laser diodes, electrical circuits may be used. The electrical circuits then generally comprise a terminal for the light-emitting component at which a supply voltage or a supply current may be provided for the light-emitting component. In addition, the electrical circuit may comprise a control input on the basis of which the supply voltage or the supply current for the light-emitting component may be controlled. Thus, the supply voltage or the supply current is switched on and off, wherein inductances within the control may have the effect that the supply voltage or the supply current is present at the light-emitting component only after a certain rise time. The rise time has the effect that the light-emitting component may not be operated such that the light-emitting component generates a short light pulse that is shorter than the rise time.

It could therefore be helpful to provide an electrical circuit with which a light-emitting component may be operated such that a short light pulse of the order of magnitude of a few nanoseconds may be generated by the light-emitting component and an operating method for such an electrical circuit that enables the short light pulses to be generated.

### SUMMARY

We provide an electrical circuit that drives a light-emitting component, the circuit including a parallel circuit including a capacitor; and a switching element, wherein a first terminal for a voltage supply connects to a first contact of the capacitor and a second terminal for a voltage supply connects to a second contact of the capacitor, the switching element includes a first electrical switch including a first input for a first switching signal, a second electrical switch including a second input for a second switching signal, and a third terminal and a fourth terminal, the third terminal and the fourth terminal form a component terminal for the light-emitting component, a first current path may be switched to be conducting by the first switch, the first current path includes the component terminal, a second current path may be switched to be conducting by the second switch, and the second current path is in parallel with the component terminal.

We also provide a method of operating the electrical circuit that drives a light-emitting component, the circuit including a parallel circuit including a capacitor; and a switching element, wherein a first terminal for a voltage supply connects to a first contact of the capacitor and a second terminal for a voltage supply connects to a second contact of the capacitor, the switching element includes a first electrical switch including a first input for a first switching signal, a second electrical switch including a second input for a second switching signal, and a third terminal and a fourth terminal, the third terminal and the fourth terminal form a component terminal for the light-emitting component, a first current path may be switched to be conducting by the first switch, the first current path includes the component terminal, a second current path may be switched to be conducting by the second switch, and the second current path is in parallel with the component terminal, including switching the second electrical switch to have continuity for electric current based on a second switching signal at the second input, switching the first switch to have continuity for electric current based on a first switching signal at the first input, switching the second electrical switch to be blocking for electric current based on a second switching signal at the second input, and switching the first switch to be blocking for electric current based on a first switching signal at the first input.

We further provide an electrical circuit that drives a light-emitting component, including a parallel circuit including a capacitor; and a switching element, wherein a first terminal for a voltage supply connects to a first contact of the capacitor and a second terminal for a voltage supply connects to a second contact of the capacitor, the switching element includes a first electrical switch including a first input for a first switching signal, a second electrical switch including a second input for a second switching signal, and a third terminal and a fourth terminal, the third terminal and the fourth terminal form a component terminal for the light-emitting component, a first current path may be switched to be conducting by the first switch, the first current path includes the component terminal, a second current path may be switched to be conducting by the second switch, the second current path is in parallel with the component terminal, the component terminal connects in parallel with the second electrical switch, and the first electrical switch connects in series with the parallel circuit comprising component terminal and second electrical switch.

We further yet provide the electrical circuit that drives a light-emitting component, including a parallel circuit including a capacitor; and a switching element, wherein a first terminal for a voltage supply connects to a first contact of the capacitor and a second terminal for a voltage supply connects to a second contact of the capacitor, the switching element includes a first electrical switch including a first input for a first switching signal, a second electrical switch including a second input for a second switching signal, and a third terminal and a fourth terminal, the third terminal and the fourth terminal form a component terminal for the light-emitting component, a first current path may be switched to be conducting by the first switch, the first current path includes the component terminal, a second current path may be switched to be conducting by the second switch, the second current path is in parallel with the component terminal, the component terminal connects in parallel with the second electrical switch, and the first electrical switch connects in series with the parallel circuit comprising component terminal and second electrical switch, wherein a light-emitting component connects to the component terminal, wherein the circuit includes conductor tracks on a printed circuit board, a first conductor track and a second conductor track are arranged on the printed circuit board, the first contact of the capacitor is a first bottom side contact and arranged on the first conductor track, the second contact of the capacitor is a second bottom side contact and arranged on the second conductor track, the light-emitting component includes a third bottom side contact and a first top side contact, the third bottom side contact is arranged on the first conductor track, the first electrical switch includes a fourth bottom side contact and a second top side contact, the fourth bottom side contact is arranged on the second conductor track, the second electrical switch includes a fifth bottom side contact and a third top side contact, the fifth bottom side contact is arranged on the first conductor track, the first top side contact connects to the second top side contact by a bond wire, and the first top side contact connects to the third top side contact by a bond wire.

### BRIEF DESCRIPTION OF THE DRAWINGS

FIG. 1 schematically shows a circuit diagram of an electrical circuit.

FIG. 2 schematically shows a circuit diagram of a further electrical circuit.

FIG. 3 schematically shows a circuit diagram of an electrical circuit with a resistor.

FIG. 4 schematically shows a circuit diagram of an electrical circuit with a light-emitting component.

FIG. 5 schematically shows a plan view of a printed circuit board with an electrical circuit.

FIG. 6 schematically shows a plan view of a further printed circuit board with an electrical circuit.

FIG. 7 schematically shows a plan view of a further printed circuit board with an electrical circuit.

FIG. 8 schematically shows a plan view of a further printed circuit board with an electrical circuit.

### LIST OF REFERENCE SIGNS

100 Electrical circuit

101 First terminal

102 Second terminal

103 Printed circuit board

104 First conductor track

105 Second conductor track

106 Third conductor track

107 Region

108 Taper

110 Component

111 Third terminal

112 Fourth terminal

113 First top side contact

120 Capacitor

121 First contact

122 Second contact

130 Switching element

131 First current path

132 Second current path

140 First electrical switch

141 First input

142 Second top side contact

150 Second electrical switch

151 Second input

152 Third top side contact

160 Resistor

161 Fifth terminal

162 Sixth terminal

170 Bond wire

### DETAILED DESCRIPTION

An electrical circuit that drives a light-emitting component comprises a parallel circuit comprising a capacitor and a switching element. A first terminal for a voltage supply connects to a first contact of the capacitor. A second terminal for a voltage supply connects to a second contact of the capacitor. The first and second terminals for the voltage supply thus provide an electrical supply voltage for the circuit and thus also for the light-emitting component. The switching element connected in parallel with the capacitor comprises a first electrical switch comprising a first input for a first switching signal, a second electrical switch comprising a second input for a second switching signal, and a third terminal and a fourth terminal. The third and fourth terminals form a component terminal for the light-emitting component. A first current path may be switched to be conducting by the first switch, wherein the first current path comprises the component terminal. A second current path may be switched to be conducting by the second switch, wherein the second current path is in parallel with the component terminal.

With such a circuit, first, the second switch may be switched to have continuity for electric current. Since the second switch is in parallel with the component terminal, the light-emitting component may thus be bridged. The current flowing on account of the supply voltage flows through the second switch. If the first current path is then switched to be conducting, the light-emitting component, at the component terminal, continues to be bridged by the second switch. If the second switch is subsequently switched to be blocking, on account of the current already flowing, the inductance of the electrical circuit changes only to a very small extent. As a result, the rise time caused by the inductance is shortened such that the full supply voltage is present at the light-emitting component within a few nanoseconds. As a result, a light pulse that is present very shortly after the corresponding switching of the electrical circuit may be generated by the light-emitting component. If the voltage supply is then interrupted by the first switch being switched to be blocking, a short light pulse of the light-emitting component comprising a pulse length of a few nanoseconds may be generated as a result.

The component terminal may connect in parallel with the second electrical switch. The first electrical switch may connect in series with the parallel circuit comprising component terminal and second electrical switch. In this example, the current flows through the first switch and the second switch before the second switch is switched to be blocking. Since an internal resistance of a light-emitting component connected to the component terminal is significantly greater than an internal resistance of the second switch, approximately no current flows through a light-emitting component connected to the component terminal. After the second switch has been switched to be blocking, however, the entire supply voltage may be present at the light-emitting component or the component terminal, wherein only the inductances of the second switch and the light-emitting component need be taken into account for the rise time.

The first switch may connect in series to the component terminal. The second switch may connect in parallel to the series circuit comprising first switch and component terminal. In this example, too, the light-emitting component is bridged via the second switch at the component terminal. If the second switch is then switched to be blocking, the entire current flows through the first switch and the light-emitting component. In this example, the inductances of the second switch, the first switch and the light-emitting component need to be taken into account for the rise time.

The first electrical switch and/or the second electrical switch may be transistors, in particular field effect transistors. Transistors or field effect transistors are well suited to a circuit for a light-emitting component with which short rise times may be realized.

A light-emitting component may connect to the component terminal. The light-emitting component is thus part of the electrical circuit or the electrical circuit is part of the light-emitting component. A compact arrangement of the light-emitting component and of the electrical circuit, for example, on a printed circuit board, may be realized as a result. The electrical circuit and the light-emitting component may be realized in an integrated circuit.

The light-emitting component may comprise a diode laser. The diode laser may comprise at least two pn junctions connected in series. The diode laser may be in particular a so-called triple junction laser comprising three pn junctions. Such a triple junction diode laser requires a supply voltage of approximately 20 volts or a supply current of approximately 30 amperes. On account of the high voltages and currents occurring on account of the supply voltage or the supply current, inductive effects are of great importance when the triple junction laser is switched on and off. The circuit thus makes it possible to operate a triple junction laser in a pulsed manner, wherein the pulse length is in the range of a few nanoseconds. With a conventional circuit consisting of a switch connected in series with the triple junction laser, pulsed operation with such short pulse lengths would not be possible.

The circuit may comprise conductor tracks on a printed circuit board. A first conductor track and a second conductor track may be arranged on the printed circuit board. The first contact of the capacitor may be a first bottom side contact and arranged on the first conductor track. The second contact of the capacitor may be a second bottom side contact and arranged on the second conductor track. The light-emitting component may comprise a third bottom side contact and a first top side contact. The third bottom side contact of the light-emitting component may be arranged on the first conductor track. The first electrical switch may comprise a fourth bottom side contact and a second top side contact. The fourth bottom side contact of the first electrical switch may be arranged on the second conductor track. The second electrical switch may comprise a fifth bottom side contact and a third top side contact. The fifth bottom side contact of the second electrical switch may be arranged on the first conductor track. The first top side contact of the light-emitting component may connect to the second top side contact of the first electrical switch by a bond wire. A compact arrangement of the light-emitting component, of the capacitor and of the electrical switches on the printed circuit board may be achieved as a result.

The first top side contact of the light-emitting component may connect to the third top side contact of the second electrical switch by a bond wire. In this example, therefore, the light-emitting component and the second electrical switch connect in parallel with one another, while the first electrical switch connects in series with the parallel circuit comprising light-emitting component and second electrical switch.

The second top side contact of the first electrical switch may connect to the third top side contact of the second electrical switch by a bond wire. In this example, therefore, light-emitting component and first electrical switch connect in series, while the series circuit comprising light-emitting component and first electrical switch connect in parallel with the second electrical switch.

The electrical circuit may furthermore comprises a resistor. The resistor may connect in series with the switching element. The electrical circuit may comprise a fifth terminal and a sixth terminal, wherein the fifth terminal and the sixth terminal are configured to tap off a voltage dropped across the resistor. By virtue of the fact that the resistor connects in series with the switching element, a voltage is dropped across the resistor during the operation of a light-emitting component at the electrical circuit, which voltage may be measured by the fifth and sixth terminals. As long as the electric current flows through the second electrical switch, that is to say the light-emitting component is bridged, the voltage drop across the electrical resistor is greater than in the operating mode in which the second electrical switch is switched to be blocking and the electric current flows through the light-emitting component. The light pulse emitted by the light-emitting component may thus be detected as a result of the change in the voltage drop across the resistor.

The electrical circuit may comprise a resistor, wherein the resistor connects in series with the switching element. The electrical circuit may comprise a fifth terminal and a sixth terminal configured to tap off a voltage dropped across the resistor. The circuit may comprise conductor tracks on a printed circuit board, wherein a first conductor track, a second conductor track and a third conductor track are arranged on the printed circuit board. The first contact of the capacitor may be a first bottom side contact and arranged on the first conductor track. The second contact of the capacitor may be a second bottom side contact and arranged on the second conductor track. The light-emitting component may comprise a third bottom side contact and a first top side contact, wherein the third bottom side contact is arranged on the third conductor track. The first electrical switch may comprise a fourth bottom side contact and a second top side contact, wherein the fourth bottom side contact is arranged on the second conductor track. The second electrical switch may comprise a fifth bottom side contact and a third top side contact, wherein the fifth bottom side contact is arranged on the third conductor track. The first top side contact may connect to the second top side contact by a bond wire. The resistor may comprise a sixth bottom side contact and a seventh bottom side contact, wherein the sixth bottom side contact is arranged on the first conductor track and the seventh bottom side contact is arranged on the third conductor track, and the fifth terminal is arranged on the first conductor track and the sixth terminal is arranged on the third conductor track.

The resistor may be a taper of a conductor track. The cost-effective production of a resistor used to detect a light pulse is possible as a result.

In a method of operating an electrical circuit, first, the second electrical switch is switched to have continuity for electric current on the basis of a second switching signal at the second input, wherein afterward the first switch is switched to have continuity for electric current on the basis of a first switching signal at the first input. After that, the second switch is switched to be blocking for electric current on the basis of the second switching signal at the second input. After that, in turn, the first switch is switched to be blocking for electric current on the basis of the first switching signal at the first input. As a result of the second switch being switched to be blocking, the electric current is directed to the component terminal and thus to the light-emitting component. As a result, the light-emitting component emits light. As a result of the first switch being switched to be blocking, the supply of current to the light-emitting component is interrupted.

The time period between switching the second switch to be blocking and switching the first switch to be blocking may be less than 10 nanoseconds, in particular less than 5 nanoseconds and in particular 2 nanoseconds. A light pulse of the light-emitting component shorter than 10 nanoseconds, in particular shorter than 5 nanoseconds, and in particular comprising a pulse length of 2 nanoseconds, is generated as a result.

The voltage dropped across the resistor may be measured by the fifth and sixth terminals. By virtue of the measured resistance, it is possible to detect whether the light-emitting component has emitted a light pulse.

The above-described properties, features and advantages and the way in which they are achieved will become clearer and more clearly understood in association with the following description of examples explained in greater detail in association with the drawings.

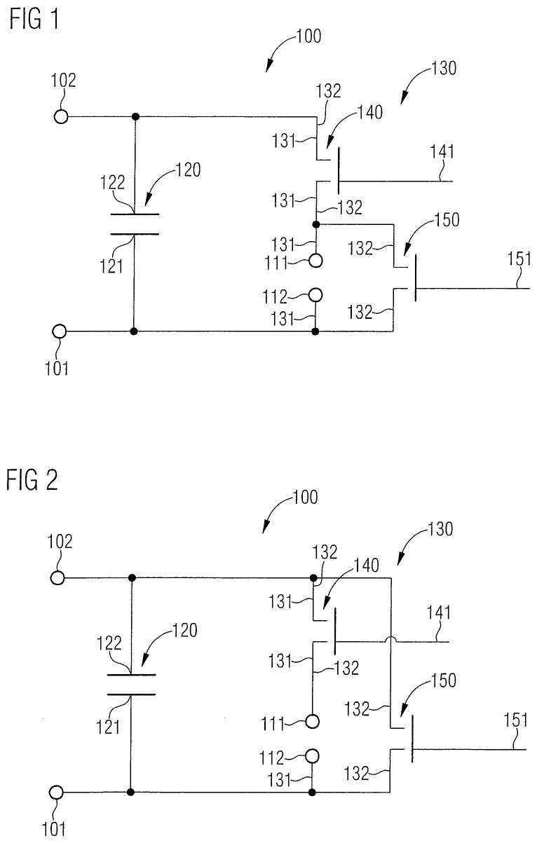

FIG. 1 shows an electrical circuit 100 that drives a light-emitting component. The electrical circuit 100 comprises a parallel circuit comprising a capacitor 120 and a switching element 130. A first terminal 101 for a voltage supply connects to a first contact 121 of the capacitor 120. A second terminal 102 of a voltage supply connects to a second contact 122 of the capacitor 120. By the first terminal 101 and the second terminal 102, an electrical supply voltage may thus be applied to the circuit 100. The switching element 130 connected in parallel with the capacitor 120 comprises a first electrical switch 140 comprising a first input 141 for a first switching signal, a second electrical switch 150 comprising a second input 151 for a second switching signal, and a third terminal 111 and a fourth terminal 112. In this example, the third terminal 111 and the fourth terminal 112 form a component terminal 111, 112, to which a light- emitting component may be connected. In this example, the component terminal 111, 112 and the second switch 150 connect in parallel with one another. The first switch 140 connects in series with the parallel circuit comprising component terminal 111, 112 and second switch 150. A first current path 131 may be switched to be conducting by the first switch 140. The first current path 131 comprises the component terminal 111, 112 and the first electrical switch 140. A second current path 132 may be switched to be electrically conducting by the second electrical switch 150, wherein the second current path 132 comprises the first switch 140 and the second switch 150. The second current path 132 is thus in parallel with the component terminal 111, 112.

FIG. 2 shows an electrical circuit 100 likewise suitable for driving a light-emitting component. The electrical circuit 100 once again comprises a parallel circuit comprising a capacitor 120 and a switching element 130. The capacitor 120 again connects by its contacts 121, 122 to a first terminal 101 and a second terminal 102 for a voltage supply, analogously to FIG. 1. The switching element 130 in FIG. 2 once again comprises a first electrical switch 140, a second electrical switch 150, and a component terminal 111, 112, consisting of a third terminal 111 and a fourth terminal 112. The component terminal 111, 112 connects in series with the first electrical switch 140. The second electrical switch 150 connects in parallel with the series circuit comprising first electrical switch 140 and component terminal 111, 112. The first electrical switch 140 once again comprises a first input 141 for a first switching signal, while the second electrical switch 150 comprises a second input 151 for a second switching signal. A first current path 131 comprises the component terminal 111, 112 and the first switch 140, wherein the first current path 131 may be switched to be electrically conducting by the first switch 140. A second current path 132 comprises the second switch 150, wherein the second current path 132 may be switched to be electrically conducting by the second switch 150.

FIGS. 1 and 2, the switching of the first electrical switch 140 and of the second electrical switch 150 may each be triggered by a corresponding switching signal at the first input 141 and at the second input 151, respectively. The electrical circuit 100 in FIGS. 1 and 2, respectively, may be operated such that, first, the second electrical switch 150 is switched to have continuity for electric current on the basis of the second switching signal at the second input 151. Afterward, the first switch 140 is switched to have conducting continuity for electric current on the basis of a switching signal at the first input 141. As a result, an electric current flows through the second switch 150 on account of a supply voltage provided at the first terminal 101 and the second terminal 102. If a light-emitting component connects to the component terminal 111, 112, then, on account of the higher internal resistance of the light-emitting component, no current flows via the first current path 131 since the entire current flows through the second switch 150 and thus via the second current path 132. If the second switch 150 is then switched to be blocking for electric current on the basis of a switching signal at the second input 151, then the current present is directed via the first current path 131 through the light-emitting component. Since the current only changes from the second current path 132 to the first current path 131, only low inductances are present within the lines during this process such that the light-emitting component connected to the component terminal 111, 112 is supplied with the supply voltage with a short response time. If, after that, the first switch 140 is switched to be blocking for electric current on the basis of the first switching signal at the first input 141, current no longer flows through the light-emitting component connected to the component terminal 111, 112, as a result of which a light pulse of the light-emitting component is ended again.

In one example, a time period between switching the second switch 150 to be blocking and switching the first switch 140 to be blocking is less than 10 ns, in particular less than 5 ns, in particular 2 ns. Short pulses in the nanoseconds range may be generated as a result.

In one example, the first electrical switch 140 is a transistor, in particular a field effect transistor. In another example, the second switch 150 is a transistor, in particular a field effect transistor.

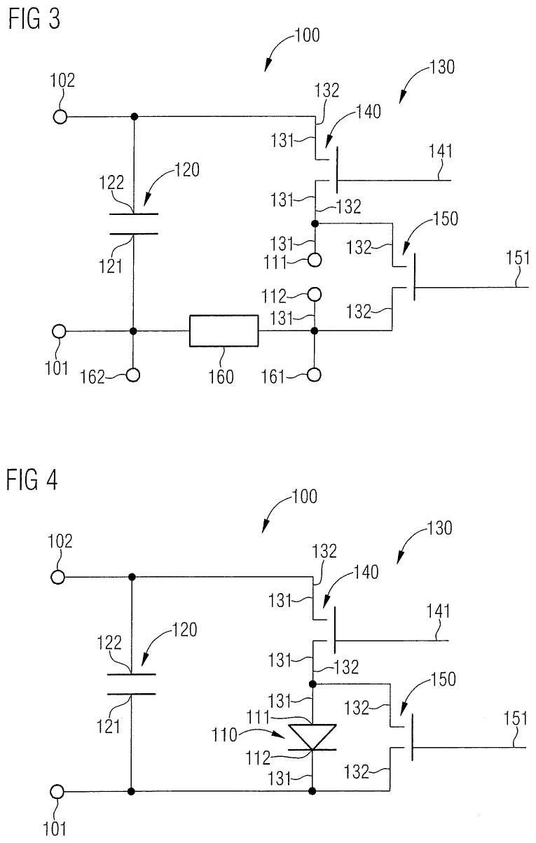

FIG. 3 shows an electrical circuit 100, constructed analogously to the electrical circuit 100 from FIG. 1. An electrical resistor 160 connects in series with the switching element 130. A fifth terminal 161 is provided on one side of the resistor 160, while a sixth terminal 162 is provided on the other side of the resistor 160. The fifth terminal 161 and the sixth terminal 162 thus tap off a voltage dropped across the resistor 160.

While the electric current flows through the second electrical switch 150, a higher voltage is dropped across the resistor 160, that is to say at the points in time at which the electric current flows through a light-emitting component connected to the component terminal 111, 112. As a result, by measuring the voltage drop by the fifth terminal 161 and the sixth terminal 162, it is possible to detect when a current flows through the light-emitting component and thus when the light-emitting component emits light.

In contrast to the illustration in FIG. 3, the arrangement of the resistor 160 in series with the switching element 130 may also be carried out such that the resistor 160 is connected in series with the switching element 130 from FIG. 2.

FIG. 4 shows an electrical circuit 100 that substantially corresponds to the electrical circuit 100 from FIG. 1. A light-emitting component 110 is arranged at the component terminal 111, 112. The light-emitting component 110 is thus integrated into the electrical circuit 100. The light-emitting component 110 may likewise be integrated into the circuit diagrams of the electrical circuits from FIGS. 2 and 3.

In one example, the light-emitting component 110 is a diode laser. In another example, the light-emitting component is a diode laser comprising at least two pn junctions connected in series, in particular a so-called triple junction diode laser comprising three pn junctions connected in series. Such a triple junction diode laser requires a supply voltage of approximately 20 volts and has an operating current of approximately 30 amperes. By virtue of these high values for the supply voltage and the operating current, reduction of the inductances during the switching process such as may be realized with the circuit 100 is particularly advantageous. By the circuit 100, a triple junction diode laser may be operated with short switching times.

FIG. 5 shows a plan view of a printed circuit board 103 on which an electrical circuit 100 is realized. In this example, the printed circuit board comprises a first conductor track 104 and a second conductor track 105. The first terminal 101 for the current supply is arranged on the first conductor track 104, while the second terminal 102 for the current supply is arranged on the second conductor track 105. The capacitor 120 comprises a first bottom side contact arranged on the first conductor track 104, and a second bottom side contact arranged on the second conductor track 105. The light-emitting component 110 comprises a third bottom side contact, wherein the light-emitting component 110 is arranged by the third bottom side contact on the first conductor track 104. Furthermore, the light-emitting component 110 comprises a first top side contact 113. The first switch 140 comprises a fourth bottom side contact and is arranged by the fourth bottom side contact on the second conductor track 105. Furthermore, the first switch 140 comprises on its top side a first input 141 for a first switching signal and a second top side contact 142. The second switch 150 comprises a fifth bottom side contact and is arranged by the fifth bottom side contact on the first conductor track 104. The second switch 150 comprises on its top side a second input 151 for a second switching signal and a third top side contact 152. The first top side contact 113 connects to the second top side contact 142 by a bond wire 170. The first top side contact 113 likewise connects to the third top side contact 152 by a bond wire 170. The electrical circuit 100 on the printed circuit board 103 is thus constructed analogously to FIG. 1.

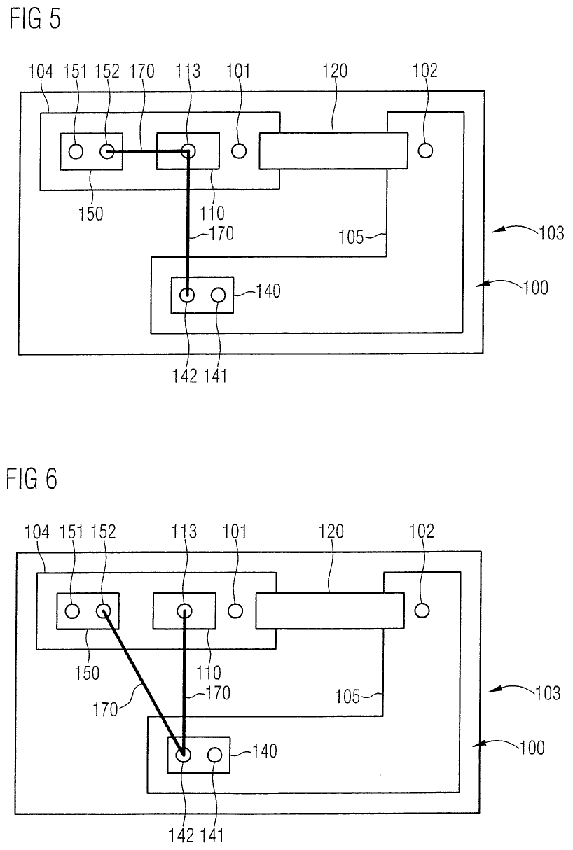

FIG. 6 shows a plan view of a printed circuit board 103 of an electrical circuit 100 that substantially corresponds to the construction of the printed circuit board 103 from FIG. 5. Just the bond wire 170 provided in FIG. 5 between the first top side contact 113 and the third top side contact 152 is not provided is not provided in the example in FIG. 6. In return, the example in FIG. 6 provides a bond wire 170 between the second top side contact 142 and the third top side contact 152. Consequently, the electrical circuit in FIG. 6 corresponds to the electrical circuit in FIG. 2.

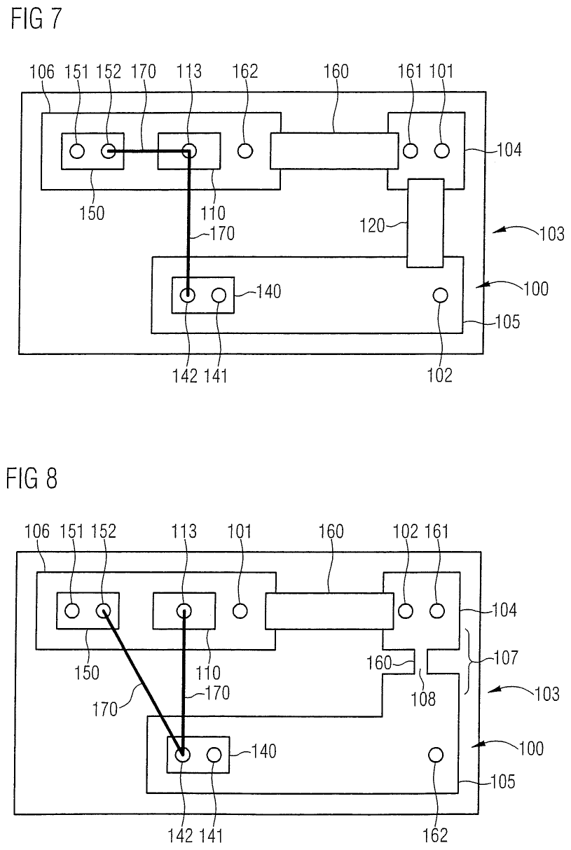

FIG. 7 shows a further printed circuit board 103 with an electrical circuit 100, wherein the printed circuit board 103 comprises a first conductor track 104, a second conductor track 105 and a third conductor track 106. The capacitor 120 is once again arranged between the first conductor track 104 and the second conductor track 105. The first electrical switch 140 is arranged by its bottom side contact on the second conductor track 105. The light-emitting component 110 is arranged by its bottom side contact on the third conductor track 106, while the second switch 150 is likewise arranged by its bottom side contact on the third conductor track 106. The first conductor track 104 once again comprises a first terminal 101 for a voltage supply, while the second conductor track 105 likewise once again comprises a second terminal for a voltage supply 102. An electrical resistor 160 is arranged between the first conductor track 104 and the third conductor track 106, wherein the resistor 160 comprises a sixth bottom side contact arranged on the first conductor track 104, and a seventh bottom side contact arranged on the third conductor track 106. A fifth terminal 161 is arranged on the first conductor track 104. A sixth terminal 162 is arranged on the third conductor track 106. A voltage drop across the resistor 160 may be detected by the fifth terminal 161 and the sixth terminal 162. The bond wires 170 in FIG. 7 are arranged analogously to FIG. 5.

Likewise, in this example, the bond wires 170 may be arranged analogously to FIG. 6. Furthermore, provision may be made for the resistor 160 not to be arranged between the first conductor track 104 and the light-emitting component 110, but rather between the capacitor 120 and the first electrical switch 140.

FIG. 8 shows a printed circuit board 103 with an electrical circuit 100 analogously to FIG. 6. At the first conductor track 104, a taper 108 is provided in a region 107 between the capacitor 120 and the first electrical switch 140. In this example, the taper 108 of the first conductor track 104 in the region 107 forms the resistor 160. In this example, the fifth terminal 161 and the sixth terminal 162 for tapping off the voltage dropped across the resistor 160 are arranged on both sides of the taper 108 of the first electrical conductor track 104 in the region 107.

Although our circuits and methods have been more specifically illustrated and described in detail by preferred examples, this disclosure is not restricted by the examples disclosed and other variations may be derived therefrom by those skilled in the art without departing from the scope of protection of the appended claims.

This application claims priority of DE 1 2017 100 879.9, the subject matter of which is incorporated herein by reference.

1-16. (canceled)

17. An electrical circuit that drives a light-emitting component, the circuit comprising:
a parallel circuit comprising a capacitor; and
a switching element,
wherein a first terminal for a voltage supply connects to a first contact of the capacitor and a second terminal for a voltage supply connects to a second contact of the capacitor,
the switching element comprises a first electrical switch comprising a first input for a first switching signal, a second electrical switch comprising a second input for a second switching signal, and a third terminal and a fourth terminal,
the third terminal and the fourth terminal form a component terminal for the light-emitting component,
a first current path may be switched to be conducting by the first switch,
the first current path comprises the component terminal,
a second current path may be switched to be conducting by the second switch, and
the second current path is in parallel with the component terminal.

18. The electrical circuit according to claim 17, wherein the component terminal connects in parallel with the second electrical switch, and the first electrical switch connects in series with the parallel circuit comprising component terminal and second electrical switch.

19. The electrical circuit according to claim 17, wherein the component terminal connects in series with the first electrical switch, and the second electrical switch connects in parallel with the series circuit comprising component terminal and first electrical switch.

20. The electrical circuit according to claim 17, wherein the first electrical switch and/or the second electrical switch are/is a transistor or a field effect transistor.

21. The electrical circuit according to claim 17, wherein a light-emitting component connects to the component terminal.

22. The electrical circuit according to claim 21, wherein the light-emitting component comprises a diode laser.

23. The electrical circuit according to claim 22, wherein the diode laser comprises at least two pn junctions connected in series.

24. The electrical circuit according to claim 21, wherein the circuit comprises conductor tracks on a printed circuit board,
a first conductor track and a second conductor track are arranged on the printed circuit board,
the first contact of the capacitor is a first bottom side contact and arranged on the first conductor track,
the second contact of the capacitor is a second bottom side contact and arranged on the second conductor track,
the light-emitting component comprises a third bottom side contact and a first top side contact,
the third bottom side contact is arranged on the first conductor track,
the first electrical switch comprises a fourth bottom side contact and a second top side contact,
the fourth bottom side contact is arranged on the second conductor track,
the second electrical switch comprises a fifth bottom side contact and a third top side contact,
the fifth bottom side contact is arranged on the first conductor track, and
the first top side contact connects to the second top side contact by a bond wire.

25. The electrical circuit according to claim 24, wherein the first top side contact connects to the third top side contact by a bond wire.

26. The electrical circuit according to claim 24, wherein the second top side contact connects to the third top side contact by a bond wire.

27. The electrical circuit according to claim 17, furthermore comprising a resistor, wherein the resistor connects in series with the switching element,
the electrical circuit comprises a fifth terminal and a sixth terminal, and
the fifth terminal and the sixth terminal are configured to tap off a voltage dropped across the resistor.

28. The electrical circuit according to claim 21, further comprising a resistor, wherein the resistor connects in series with the switching element,
the electrical circuit comprises a fifth terminal and a sixth terminal,
the fifth terminal and the sixth terminal are configured to tap off a voltage dropped across the resistor,
the circuit comprises conductor tracks on a printed circuit board,
a first conductor track, a second conductor track and a third conductor track are arranged on the printed circuit board,
the first contact of the capacitor is a first bottom side contact and arranged on the first conductor track,
the second contact of the capacitor is a second bottom side contact and arranged on the second conductor track,
the light-emitting component comprises a third bottom side contact and a first top side contact,
the third bottom side contact is arranged on the third conductor track,
the first electrical switch comprises a fourth bottom side contact and a second top side contact,
the fourth bottom side contact is arranged on the second conductor track,
the second electrical switch comprises a fifth bottom side contact and a third top side contact,
the fifth bottom side contact is arranged on the third conductor track,
the first top side contact connects to the second top side contact by a bond wire,
the resistor comprises a sixth bottom side contact and a seventh bottom side contact,
the sixth bottom side contact is arranged on the first conductor track and the seventh bottom side contact is arranged on the third conductor track, and
the fifth terminal is arranged on the first conductor track and the sixth terminal is arranged on the third conductor track.

29. The electrical circuit according to claim 27, wherein the resistor is a taper of a conductor track.

30. A method of operating the electrical circuit according to claim 17, comprising:
switching the second electrical switch to have continuity for electric current based on a second switching signal at the second input,
switching the first switch to have continuity for electric current based on a first switching signal at the first input,
switching the second electrical switch to be blocking for electric current based on a second switching signal at the second input, and
switching the first switch to be blocking for electric current based on a first switching signal at the first input.

31. The method according to claim 30, wherein a time period between switching the second switch to be blocking and switching the first switch to be blocking is less than 10 nanoseconds.

32. The method according to claim 30, wherein the voltage dropped across the resistor is measured by the fifth terminal and the sixth terminal.

33. An electrical circuit that drives a light-emitting component, comprising:
a parallel circuit comprising a capacitor; and
a switching element,
wherein a first terminal for a voltage supply connects to a first contact of the capacitor and a second terminal for a voltage supply connects to a second contact of the capacitor,
the switching element comprises a first electrical switch comprising a first input for a first switching signal, a second electrical switch comprising a second input for a second switching signal, and a third terminal and a fourth terminal,
the third terminal and the fourth terminal form a component terminal for the light-emitting component,
a first current path may be switched to be conducting by the first switch.
the first current path comprises the component terminal,
a second current path may be switched to be conducting by the second switch,
the second current path is in parallel with the component terminal,
the component terminal connects in parallel with the second electrical switch, and
the first electrical switch connects in series with the parallel circuit comprising component terminal and second electrical switch.

34. The electrical circuit according to claim 33, wherein a light-emitting component connects to the component terminal.

35. The electrical circuit according to claim 34, wherein the circuit comprises conductor tracks on a printed circuit board,
a first conductor track and a second conductor track are arranged on the printed circuit hoard,
the first contact of the capacitor is a first bottom side contact and arranged on the first conductor track,
the second contact of the capacitor is a second bottom side contact and arranged on the second conductor track,
the light-emitting component comprises a third bottom side contact and a first top side contact,
the third bottom side contact is arranged on the first conductor track,
the first electrical s itch comprises a fourth bottom side contact and a second top side contact,
the fourth bottom side contact is arranged on the second conductor track,
the second electrical switch comprises a fifth bottom side contact and a third top side contact,
the fifth bottom side contact is arranged on the first conductor track,
the first top side contact connects to the second top side contact by a bond wire, and
the first top side contact connects to the third top side contact by a bond wire.
